(19) United States
(12) Patent Application Publication
(10) Pub. No.: US 2015/0279770 A1
(43) Pub. Date: Oct. 1, 2015

(54) PACKAGE, SEMICONDUCTOR DEVICE, AND SEMICONDUCTOR MODULE

(71) Applicant: CANON KABUSHIKI KAISHA, Tokyo (JP)

(72) Inventors: Ichiro Kataoka, Kawasaki-shi (JP); Tadashi Kosaka, Atsugi-shi (JP); Takanori Suzuki, Tokyo (JP)

(21) Appl. No.: 14/658,485

(22) Filed: Mar. 16, 2015

(30) Foreign Application Priority Data
Mar. 26, 2014 (JP) 2014-064345

(51) Int. Cl. H01L 23/498; H05K 1/03; H01L 23/053

(52) U.S. Cl. CPC H01L 23/49822; H01L 23/49838; H01L 23/053; H05K 1/0306; H05K 2201/09036

(57) ABSTRACT

A package for mounting a semiconductor element includes a substrate including an upper face having a region where a semiconductor element is mounted, a lower face positioned on a side opposite to the upper face, and a side face connecting the upper face and the lower face and an electrode formed on the side face to extend in a direction from the lower face to the upper face. A width of the electrode at a first height in the direction from the lower face to the upper face is smaller than that of the electrode at a second height closer to the upper face than the first height in the direction from the lower face to the upper face.

### BACKGROUND OF THE INVENTION

1. Field of the Invention

The present invention relates to a package for mounting a semiconductor element, a semiconductor device, and a semiconductor module.

2. Description of the Related Art

Examples of packages for mounting semiconductor elements are as follows. Examples of packages including lead terminals are an SOP (Single Outline Package) and QFP (Quad Flat Package) in each of which a lead terminal extends from a side face of the package. Examples of packages including no lead terminals are an LCC (Leadless Chip Carrier) and LGA (Land Grid Array).

The LCC type package includes a plurality of electrodes each having a semi-circular arch shape obtained by longitudinally cutting a through hole in half, on a side face of a package made of, for example, ceramic. The LCC type package is also used as a package for a solid state image sensor such as a CCD or CMOS or for a MEMS. When mounting this LCC type package on a circuit board, the electrodes on the package side face and electrodes on the circuit board are aligned and joined by solder.

However, the LCC type package is weak against a thermal stress because the outer side face of the package is fixed by soldering. That is, if the difference between the thermal expansion coefficients of the package and circuit board is large, a stress occurs in the solder joint due to a thermal stress such as a temperature cycle. Consequently, the solder joint sometimes breaks and causes an electrical joint defect.

Japanese Patent Laid-Open No. 08-186002 has disclosed the structure of a chip-like electronic part which improves the solder joint strength between the electrodes formed on the side face and the electrodes on the circuit board. More specifically, the size of an opening having a semi-circular arch shape in which the electrode is formed is made larger on the package rear surface side to be joined to the circuit board than on the package front surface side. Accordingly, a solder meniscus generated when joining the electrodes on the circuit board and the electrodes of the package by solder can be formed in a sufficiently wide region. Since the area in which the electrodes of the electronic part and the electrodes of the circuit board are in contact with each other is large, it is possible to form a strong solder joint and improve the reliability of the joint.

It is, however, difficult to apply the structure of the above-mentioned patent literature to a fine-pitch LCC type package having a small inter-electrode distance. That is, the distance between the electrodes to be soldered to the circuit board is small. When joining these electrodes to the electrodes on the circuit board by solder, therefore, the solder flows between adjacent electrodes 3, that is, so-called solder bridges 41 readily form.

The present invention provides a package for mounting a semiconductor element, which suppresses the formation of the solder bridge.

### SUMMARY OF THE INVENTION

According to one aspect of the present invention, there is provided a package for mounting a semiconductor element comprising a substrate including an upper face having a region where a semiconductor element is mounted, a lower face positioned on a side opposite to the upper face, and a side face connecting the upper face and the lower face and an electrode formed on the side face to extend in a direction from the lower face to the upper face, wherein a width of the electrode at a first height in the direction from the lower face to the upper face is smaller than that of the electrode at a second height closer to the upper face than the first height in the direction from the lower face to the upper face.

Further features of the present invention will become apparent from the following description of exemplary embodiments with reference to the attached drawings.

### BRIEF DESCRIPTION OF THE DRAWINGS

FIGS. 1A and 1B are schematic views showing a package of the first embodiment and a circuit board;

FIGS. 2A to 2D are schematic views showing a state in which a semiconductor element is mounted on the package of the first embodiment;

FIGS. 3A and 3B are perspective views showing a package of the second embodiment; and

FIG. 4 is a view showing a state in which solder bridges are formed.

### DESCRIPTION OF THE EMBODIMENTS

Embodiments of the present invention will be explained in detail below with reference to the accompanying drawings. Note that the embodiments to be explained below are examples, and the present invention is not limited to these embodiments.

### First Embodiment

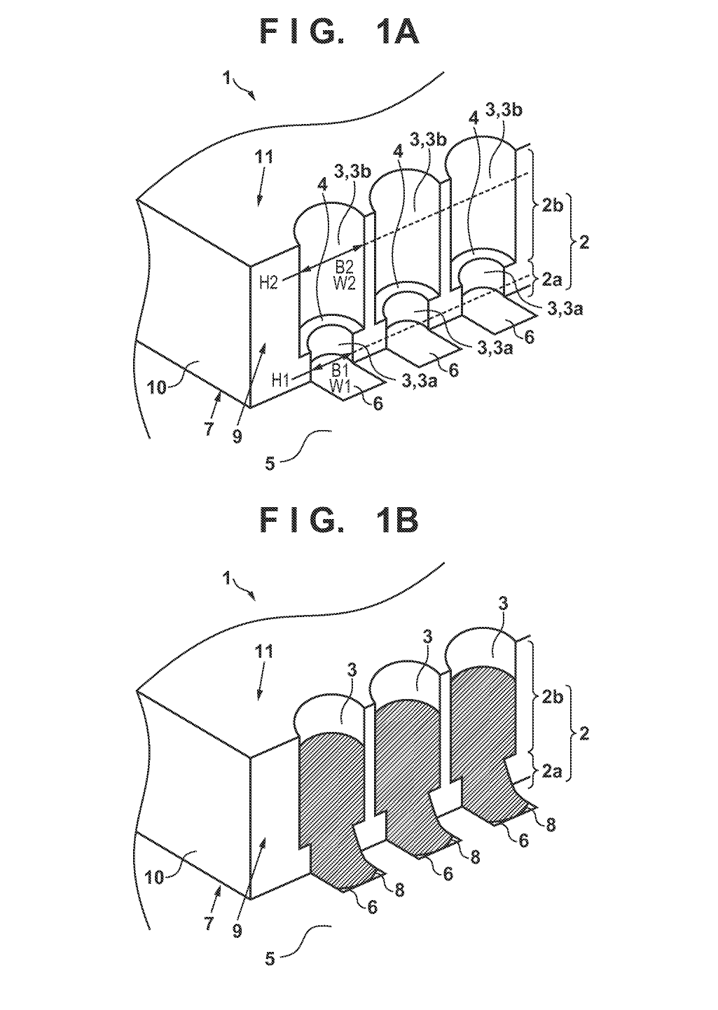

FIG. 1A shows a state in which a package 1 of this embodiment is placed in accordance with the positions of electrodes 6 of a circuit board 5. The package 1 includes an almost plate-like substrate 10 made of an insulator such as ceramic or a resin, and electrodes 3 formed on the surface of the substrate 10. The package 1 can further include a lid member and sealing material for sealing a semiconductor element. The substrate 10 has a lower face 7 of the substrate 10 as the bottom face of the package 1, which opposes the circuit board 5, and an upper face 11 including a region where a semiconductor element is placed. In addition, the substrate 10 has a side face 9 connecting the upper face 11 and the lower face 7 positioned on the side opposite to the upper face 11. The side face 9 extends from the edge of the lower face 7 to the edge of the upper face 11. In this example, the upper face 11 has a step so as to form a cavity (not shown) in its central region. This central region of the upper face 11, which is the bottom face of the cavity, is a region where a semiconductor element is placed. Also, the substrate 10 includes a frame part (not shown) formed in the peripheral region of the upper face 11 in order to form the above-mentioned step on the upper face 11. The inner surface of the frame part is so formed as to surround the space in which a semiconductor element is mounted. The outer wall of the frame part forms the upper part of the side face 9. A terminal (not shown) such as a bonding pad is formed on the upper face 11. This terminal is electrically connected to the electrode 3 by a line formed in the interior of or on the surface of the substrate 10. This terminal is electrically connected to a terminal of a semiconductor element by a method using a connecting material such as wire bonding connection or flip chip connection. As a practical semiconductor element mounting method, a semiconductor element is mounted inside the frame part of the package 1. After that, it is possible to selectively use a method of embedding the semiconductor element in the interior of the package 1 by using a sealing material such as a resin, or a method of sealing the semiconductor element by a lid member by using the inside of the package as a cavity. In this embodiment, the substrate 10 having the cavity obtained by forming the step on the upper face 11 is taken as an example. However, it is also possible to use a flat surface as the upper face 11, and place a semiconductor element in the central region of the flat surface.

Recessed grooves 2 are formed in the side face 9 of the substrate 10. Each groove 2 includes a lower groove 2a in a portion of the side face 9 on the side of the lower face 7, and an upper groove 2b in a portion of the side face 9 on the side of the upper face 11. The electrode 3 is formed along the inner surface of the groove 2. A portion of the electrode 3, which is formed in the lower groove 2a, is an electrode lower part 3a. A portion of the electrode 3, which is formed in the upper groove 2b, is an electrode upper part 3b. The groove 2 and electrode 3 extend in a direction from the lower face 7 to the upper face 11. The width of the lower groove 2a is made smaller than that of the upper groove 2b. Also, the width of the electrode 3 formed along the inner surface of the groove is set such that the electrode lower part 3a positioned in the lower groove 2a is formed to be narrower than the electrode upper part 3b positioned in the upper groove 2b. That is, the electrode 3 is formed on the inner surface of the recessed groove 2 so as to decrease the width at a height H1 on the side of the lower face 7 of the package, and increase the width at a height H2 on the side of the upper face 11. The heights H1 and H2 herein mentioned are positions on the side face 9 in the direction from the lower face 7 to the upper face 11. The height H1 is closer to the lower face 7 than the height H2, and the height H2 is closer to the upper face 11 than the height H1. Let H be the length of the side face 9 in the direction from the lower face 7 to the upper face 11 (the length H is equal to the distance between the upper face 11 and lower face 7, and to the thickness of the substrate 10). A position where the height H is 0 is the boundary between the lower face 7 and side face 9, and a position where the height is H is the boundary between the upper face 11 and side face 9. H1 may be equal to 0, and H2 may be equal to H.

A step 4 exists between the lower groove 2a and upper groove 2b. Since the electrode 3 is formed on the step 4 as well, solder easily wets and spreads from the lower groove 2a toward the upper groove 2b. Thus, the electrode upper part 3b can continue to the electrode lower part 3a. Since the electrode 3 is formed in the groove 2, solder enters the groove 2 when soldering the electrode 3. This makes it possible to obtain a wider solder joint area and a solder amount sufficient for joining, thereby further strengthening the solder joint.

A plurality of grooves 2 each having a semi-circular arch shape are formed in the side face 9 of the substrate 10 so as to extend in the direction from the lower face 7 to the upper face 11 of the substrate 10. The width of the groove 2 is set such that a width B2 at the height H2 on the side of the upper face 11 of the package 1 is larger than a width B1 at the height H1 on the side of the lower face 7 of the substrate of the package 1, to which the circuit board 5 is attached. The width of the electrode 3 formed in the groove 2 is also set such that a width W2 of the electrode upper part 3b at the height H2 of the side face 9 on the side of the upper face 11 is larger than a width W1 of the electrode lower part 3a at the height H1 of the side face 9 on the side of the lower face 7. Note that the width of the electrode 3 herein mentioned is the width of the electrode viewed parallel to the lower face 7 of the substrate of the package 1. When the electrode 3 is formed on the inner surface of the recessed groove 2 having a semi-circular arch shape as in this embodiment, the length of the semi-circular arch is a width W of the electrode 3. The width W of the electrode 3 at a given height is equal to a width B of the groove 2 (B=W). However, it is also possible to form the electrode 3 on only a portion of the inner surface of the groove 2, and make the width W of the electrode 3 smaller than the width B of the groove 2 (W<B).

The electrode 3 formed on the inner surface of the groove is electrically connected to a terminal (bonding pad) on the upper face 11 of the package 1 by an internal line of the substrate 10, and a semiconductor element mounted on the package is electrically connected to the terminal by a bonding wire. As shown in FIG. 1B, the electrode 3 is connected to an electrode 6 of the circuit board 5 by solder 8.

When soldering the package 1 to the circuit board 5, the supply amount to the lower groove 2a of the package 1 becomes larger than that to the upper groove 2b of the package 1 due to the weight of the molten solder. As a consequence, a solder bridge readily forms if the distance between adjacent electrodes 3 is small. In this embodiment, the width W1 of the electrode lower part 3a positioned in the lower groove 2a of the side face 9 is smaller than the width W2 of the electrode upper part 3b positioned in the upper groove 2b of the side face 9. This makes it possible to increase the distance between the electrodes 3 in the lower part of the package 1, thereby suppressing the formation of a solder bridge. On the other hand, the width of the electrode on the upper side face of the package 1 increases. Since the upper part of the electrode 3 is joined to the electrode 6 of the circuit board by solder, a sufficient solder joint strength can be obtained. Accordingly, this embodiment can suppress the formation of a solder bridge and sufficiently increase the solder joint strength.

The recessed groove 2 in the side face 9 of the substrate 10 has a shape obtained by longitudinally splitting a through hole formed in a direction perpendicular to the bottom face of the package 1. The groove 2 of the substrate 10 can be formed to have this semi-circular arch structure by forming a through hole in a ceramic substrate. A ceramic material (green sheet) having a large-diameter through hole and a ceramic material (green sheet) having a small-diameter through hole are formed such that the position of each through hole is the prospective position of the electrode 3. Then, the two ceramic materials are laminated and bonded so that the through hole positions overlap each other. After being bonded, the two ceramic materials are longitudinally split in the positions of the through holes, so that a portion having a large through hole diameter is the upper part of the package, and a portion having a small through hole diameter is formed as the lower part of the package. It is also possible to form the electrode 3 on the entire inner surface of the through hole by metallization, and form an electrode on the step 4 after the multilayer ceramic is split, or form the electrode 3 in the groove 2 after the ceramic substrate is split. The semi-circular arch electrode 3 is formed on the side face of the package 1 by longitudinally splitting the through hole in half. The package of this embodiment can be formed relatively easily by making the substrate 10 as multilayer ceramic.

There is no limitation on the through hole diameter for forming the electrode 3, and the through hole diameter can be set to about 0.3 to 0.6 mm for a package in which the height of the side face (which is the length from the lower face to the upper face, and equivalent to the thickness of the substrate 10) is about 1 to 3 mm. Also, the height of the electrode lower part 3a in the lower groove 2a of the package can be set to about 5% to 50% of the height of the package. If the height of the electrode lower part 3a in the lower groove 2a is less than 5% of the height of the package, solder readily flows around the lower groove 2a, and this decreases the effect of suppressing the formation of a solder bridge. On the other hand, if the height of the electrode lower part 3a in the lower groove 2a exceeds 50% of the height of the package, the distance between the electrode in the upper groove 2b of the package and the electrode 6 of the circuit board 5 increases. This makes it difficult for solder to adhere to the electrode in the upper groove 2b, so a decrease in solder joint strength becomes no longer negligible.

For example, when the package height is about 2 mm, the through hole diameter for forming a recessed groove as the lower groove 2a is about 0.3 mm. The through hole diameter for forming a recessed groove as the upper groove 2b is about 0.5 mm. Also, when the height of the electrode in the lower groove 2a is about 0.5 mm and the electrode pitch (spacing) is about 0.7 mm, it is possible to sufficiently strengthen the solder joint, and suppress the formation of a solder bridge.

Gold plating can be performed on the surface of the electrode 3 on the inner surface of the recessed groove 2. The electrode 3 on the inner surface of the recessed groove 2 need only have an electrode width which is larger in the upper part than in the lower part of the package 1, so the electrode may also be formed not on the whole but on a part of the inner surface of the groove 2 from the lower face 7 of the substrate 10 toward the upper part of the package 1. It is also possible to use the same through hole diameter for forming the groove 2 in the lower and upper parts of the package 1, and make the width of the electrode 3 to be formed on the inner surface of the groove 2 larger in the upper part than in the lower part of the package 1. In this case, solder comes in contact with the electrode in a relatively large area in the upper part, and comes in contact with the electrode in a small area in the lower part. This makes it possible to suppress a leakage of the solder to the periphery in the lower part of the groove 2, and sufficiently strengthen the joint. When the package height is 1 to 3 mm, the ratio of the width at the lower end of the electrode 3 on the lower face side of the package 1 to the width at the upper end of the electrode 3 is set not less than 1.2 and not more than 3.0. This makes it possible to sufficiently increase the joint strength, and suppress a solder bridge.

When mounting the package 1 on the circuit board 5, the package 1 is placed such that the electrode 6 of the circuit board 5, which is coated with solder paste, is parallel to the lower face 7 of the package and perpendicular to the side face of the package. In this state, position adjustment is so performed that the central line of the electrode 6 of the circuit board 5 is aligned with the central line of the electrode 3 on the side face of the package 1. After that, the electrode 3 and the electrode 6 of the circuit board 5 are joined by solder in a reflow furnace. As shown in FIG. 1B, solder melted by heat wets and spreads to the electrode 3 on the side face of the package 1. In this state, the solder also wets and spreads to the upper part of the package 1 from the lower part of the package 1, which is close to the circuit board. The solder to be used to join the electrode 3 of the package 1 and the electrode 6 of the circuit board 5 may have an Sn—Ag—Cu-based composition, and may also have, for example, an Sn—Bi-based composition.

In the package of this embodiment, the spacing between adjacent electrodes in the lower part of the package 1 is wider than that between adjacent electrodes in the upper part. This suppresses the formation of a solder bridge in soldering. At the same time, solder wets and spreads even to the upper part of the package 1 where the width of the electrode 3 is large, so a solder joint is obtained even in the upper part of the package where the electrode width is large. This implements a strong solder joint. Therefore, it is possible to suppress the break of the solder joint caused by a thermal stress such as a temperature cycle, and obtain a highly reliable package for mounting a semiconductor element. Note that in the above-mentioned embodiment, the example in which the groove 2 is formed in the side face 9 of the substrate 10 and the electrode 3 is formed along the inner surface of the groove 2 has been explained. However, it is also possible to use a flat surface as the side face 9 without forming the groove 2 in the side face 9. In this case, a planar electrode 3 having a small width in the lower part and a large width in the upper part need only be formed on the flat side face 9.

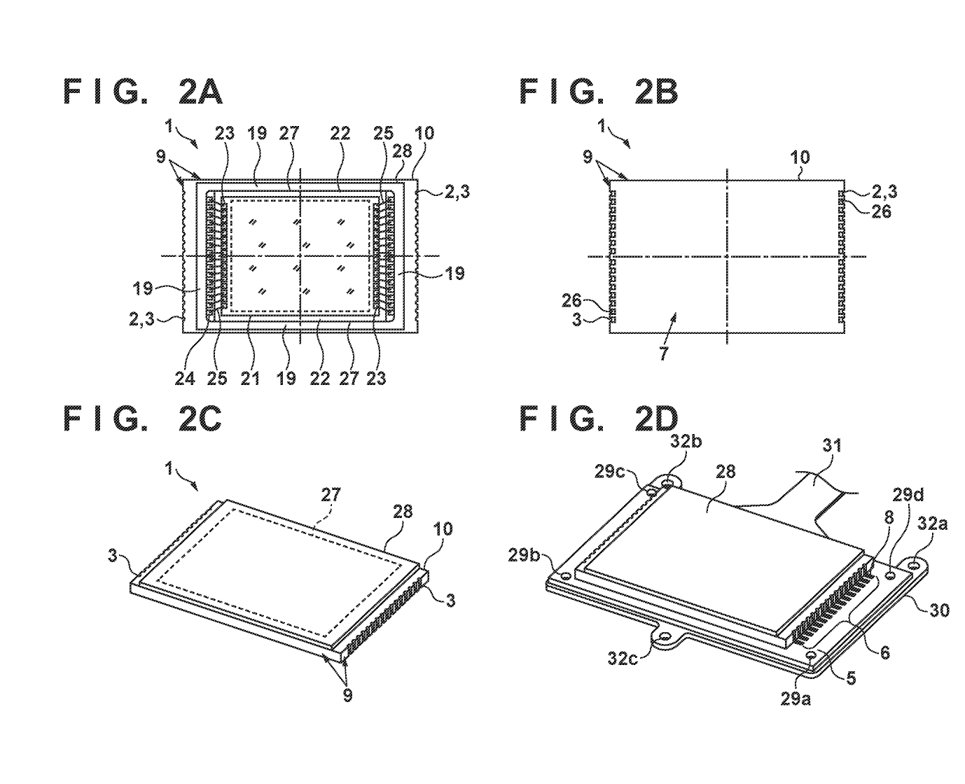

Next, an example of a semiconductor device obtained by mounting a semiconductor element on the package 1 of this embodiment will be explained with reference to FIGS. 2A to 2D. FIG. 2A is a plan view showing the upper face 11 of the substrate 10 shown in FIG. 1A, and FIG. 2B is a plan view showing the lower face 7 of the substrate 10 shown in FIG. 1A. A solid-state image sensor 21 is mounted as a semiconductor element in this example, but the semiconductor element is not limited to the solid-state image sensor 21. The same reference numerals denote the same constituent elements in FIGS. 1A and 1B. The solid-state image sensor 21 is placed in a recess 22 of the substrate 10 of the package 1. The solid-state image sensor 21 is surrounded by a frame part 19. The electrodes 3 are formed on the side face 9 of the substrate 10. The electrode 3 is formed along the inner surface of the groove 2. A plurality of bonding pads 23 of the solid-state image sensor 21 and a plurality of bonding pads 24 formed inside the frame part 19 of the package 1 are connected by bonding wires 25. The bonding pads 24 inside the package 1 and the electrodes 3 on the side face 9 of the substrate 10 are connected by lines formed in the interior of the frame part 19. The upper ends of the grooves 2 and electrodes 3 reach the upper face 11 in this example, but they need not reach the upper face 11. It is also possible to form neither the grooves 2 nor the electrodes 3 on the outer wall of the frame part 19, which forms the upper part of the side face 9, and form the grooves 2 and electrodes 3 in only the lower part of the side face 9. The electrodes 3 may also extend to at least one of the upper face 11 and lower face 7 from the side face 9. In this example, the electrodes 3 on the side face of the package 1 are continuously connected to electrodes 26 formed on the lower face 7 of the substrate of the package 1, as shown in a rear surface view of the package 1 in FIG. 2B. The electrodes 26 are so formed as to extend the electrodes 3, and strengthen the joint between the circuit board and package.

In this example, a transparent lid member 28 is formed in the upper part opposing the recess 22 of the substrate 10 on which the solid-state image sensor 21 is placed. Light passing through the lid member 28 opposing the solid-state image sensor 21 can enter the solid-state image sensor 21 placed on the package 1. As shown in FIG. 2C, the lid member 28 is fixed to the upper face of the frame part 19 by an adhesive. The semiconductor element may also be sealed with a resin inside the recess 22.

An example in which a semiconductor module is obtained by fixing the semiconductor device to the circuit board will be explained below. As shown in FIG. 2D, the package 1 on which the solid-state image sensor 21 is mounted is connected to the electrodes 6 of the circuit board 5 by the solder 8. Attaching holes 29a to 29d for attaching an apparatus are formed in the circuit board 5, so the circuit board 5 can directly be attached to the apparatus. It is also possible to attach the circuit board 5 to a holding plate 30 as shown in FIG. 2D, and attach the holding plate 30 to an apparatus such as a camera. A flexible circuit board 31 to be connected to another circuit is connected to the circuit board 5. The circuit board 5 is attached to an apparatus by attaching holes 32a to 32c formed in the holding plate 30, and a signal line, power supply line, and the like are connected to the apparatus by the flexible circuit board 31. Thus, a semiconductor module is formed by soldering the package 1 on which the semiconductor element is mounted to the circuit board 5. This facilitates handling the semiconductor element.

### Second Embodiment

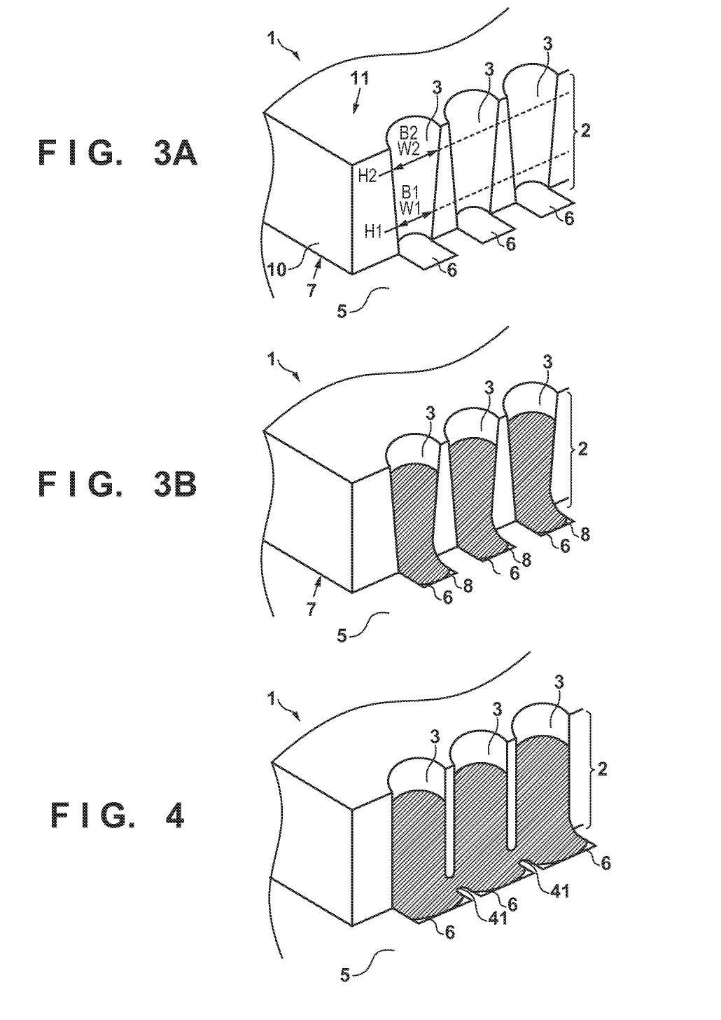

This embodiment will be explained with reference to FIGS. 3A and 3B. Electrodes 3 are formed along the inner surfaces of recessed grooves 2 formed on the surface of a side face of a substrate 10 in this embodiment as well. Each groove 2 is formed by a conical through hole which gradually increases the opening diameter from a lower face 7 of the substrate, on which a package 1 is to be soldered, toward the upper face of the package 1. The electrode 3 is formed on the entire inner surface of the recessed groove 2 having a semi-conical shape obtained by longitudinally splitting the conical through hole. Accordingly, a width W2 of the electrode 3 at a height H2 on the side of an upper face 11 of the package 1 is larger than a width W1 of the electrode 3 at a height H1 on the side of the lower face 7 of the substrate. Gold plating can be performed on the surface of the electrode 3 in order to improve the joinability of solder.

For example, when the height of the package is 2 mm, the through hole diameter for forming a recessed groove in the lowermost part of the package 1 is about 0.3 mm, and the through hole diameter for forming a recessed groove in the uppermost part of the package 1 is about 0.5 mm. Also, the pitch of the electrodes on the side face is about 0.7 mm. When the ratio of the electrode width at the lower end to the electrode width at the upper end is set at 1.2 (inclusive) to 3.0 (inclusive), it is possible to strengthen the joint, and suppress a solder bridge.

When this package is joined to electrodes of a circuit board by solder in the same manner as in the first embodiment, the spacing between adjacent electrodes is wide in the lower part of the side face of the package. This suppresses the formation of a solder bridge in soldering. At the same time, solder wets and spreads even to the upper part of the package 1 where the width of the electrode 3 is large, thereby forming a sufficiently strong solder joint.

As described above, when the electrodes of the side face of the package of this embodiment are joined by solder to the electrodes of the circuit board, it is possible to suppress the formation of a solder bridge, and achieve a strong solder joint. Therefore, a highly reliable package can be provided by suppressing the break of the solder joint caused by a thermal stress such as a temperature cycle. When a semiconductor element is mounted on the package of this embodiment, the package can be used as a semiconductor device or semiconductor module as described in the first embodiment.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-064345, filed, Mar. 26, 2014, which is hereby incorporated by reference herein in its entirety.

What is claimed is:

1. A package for mounting a semiconductor element, the package comprising:
a substrate including an upper face having a region where a semiconductor element is mounted, a lower face positioned on a side opposite to the upper face, and a side face connecting the upper face and the lower face; and
an electrode formed on the side face to extend in a direction from the lower face to the upper face,
wherein a width of the electrode at a first height in the direction from the lower face to the upper face is smaller than that of the electrode at a second height closer to the upper face than the first height in the direction from the lower face to the upper face.

2. The package according to claim 1, wherein the electrode is formed along an inner surface of a groove formed in the side face.

3. The package according to claim 2, wherein the inner surface of the groove has a shape of a semi-circular arch.

4. The package according to claim 1, wherein the width of the electrode gradually increases from the first height to the second height.

5. The package according to claim 3, wherein a diameter of the semi-circular arch of the inner surface at the first height is smaller than that of the semi-circular arch of the inner surface at the second height.

6. The package according to claim 1, wherein a ratio of the width of the electrode at the first height to the width of the electrode at the second height is not less than 1.2 and is not more than 3.0.

7. The package according to claim 1, wherein the substrate comprises multilayer ceramic.

8. The package according to claim 1, wherein the electrode is formed to extend to the lower face.

9. A semiconductor device comprising a semiconductor element mounted on the upper face of the substrate of a package cited in claim 1.

10. The device according to claim 9, wherein the substrate includes a frame part, and a lid member opposing the semiconductor element is fixed to the frame part.

11. A semiconductor module comprising a semiconductor device cited in claim 9, which is mounted on a circuit board by soldering.
